(19) United States
(12) Patent Application Publication
(10) Pub. No.: US 2024/0289602 A1
(43) Pub. Date: Aug. 29, 2024

(54) MACRO PLACEMENT USING AN ARTIFICIAL INTELLIGENCE APPROACH

(71) Applicant: MediaTek Inc., Hsinchu City (TW)

(72) Inventors: Da-Shan SHIU, Hsinchu City (TW); Alexandru CIOBA, Cambridge (GB); Fu-Chieh CHANG, Hsinchu City (TW)

(21) Appl. No.: 18/042,423

(22) PCT Filed: Oct. 12, 2022
(86) PCT No.: PCT/CN2022/124863

§ 371 Date: Feb. 21, 2023

Related U.S. Application Data
(60) Provisional application No. 63/254,582, filed on Oct. 12, 2021.

(51) Int. Cl. G06N 3/08

(52) U.S. Cl. CPC G06N 3/08

(57) ABSTRACT

A system uses a neural network (NN) for macro placement. The system receives an input including objectives and a subspace of preferences. Each preference is a vector of weights assigned to corresponding objectives, and each objective is a measurement of a placement characteristic. The system trains the NN to place macros on a training set of chips to optimize a reward, where the reward is calculated from the objectives and the preferences. The NN generates a probability distribution of an action under a current state of a chip, where the action indicates a coordinate on the chip to place a macro. The NN further generates a sequence of (state, action) pairs to form a trajectory. The final state in the trajectory corresponds to a completed macro placement.

### CROSS-REFERENCE TO RELATED APPLICATIONS

This application claims the benefit of U.S. Provisional Application No. 63/254,582 filed on Oct. 12, 2021, the entirety of which is incorporated by reference herein.

### TECHNICAL FIELD

Embodiments of the invention relate to methods and apparatuses based on machine learning and artificial intelligence (AI) for generating a macro placement on a semiconductor chip.

### BACKGROUND

In an integrated circuits (IC) design, a macro is a set of circuit components that can be viewed as a black box. The logic and electronic behavior of the macro are given but the internal structural description may or may not be known. Mixed-size macro placement is the problem of placing macros of various sizes on a chip canvas to optimize an objective such as the wirelength. The macro placement problem is further complicated when there are multiple objectives to achieve.

Design objectives may be estimated inaccurately at the early stage of the design process. For example, while total wirelength is positively correlated with power consumption, the actual mathematical relation that connects a wirelength estimate with a power consumption estimate is usually not known until after a number of prototypes very similar to the final design are implemented and characterized. Other reasons for inaccurate estimates of objectives may include: a compromise to speed up computation; assuming a form that is more amenable to optimization; shifting manufacturing parameters over time, especially for leading-edge processing nodes; objectives learned from a different context, e.g., learning from a 7 nm process to apply to 5 nm.

Moreover, the desired trade-off among various objectives is often not precisely known until much later in the design process. As the design time of a modern system-on-a-chip (SoC) can last over a year, the customers' demand may have shifted during the design process. Manufacturing parameters for leading-edge processing nodes may have also shifted over time. Furthermore, contextual implication within the overall SoC is also a factor. For example, while congestion is strongly related to the ease of downstream tasks, the amount of congestion that can be tolerated depends on other contextual factors, such as the number of feed-through wires to be supported by the circuit being placed. This is not known until the locations of various other circuits making up the SoC are frozen.

Thus, there is a need for improving the tools for macro placement such that the tools can handle the delayed knowledge of design objectives and tradeoffs.

### SUMMARY

In one embodiment, a method is provided for macro placement by a neural network (NN). The method includes receiving an input including a plurality of objectives and a subspace of preferences. Each preference is a vector of weights assigned to corresponding objectives, and each objective is a measurement of a placement characteristic. The method further includes training the NN to place macros on a training set of chips to optimize a reward calculated from the objectives and the preferences. The NN then generates a probability distribution of an action under a current state of a chip, the action indicating a coordinate on the chip to place a macro. The NN also generates a sequence of (state, action) pairs to form a trajectory, wherein a final state in the trajectory corresponds to a completed macro placement.

In another embodiment, a method is provided for training an NN to perform macro placement. The method comprises receiving a set of target trajectories that correspond to placements of respective macros on respective chips in a training set. The final state in each target trajectory corresponds to the completion of a target placement. The method further comprises searching for a reward function that generates a target reward greater than a learned reward, wherein the target reward is calculated from the target trajectories and the learned reward is calculated from trajectories generated by the NN. The method further comprises searching for parameters to update the NN such that the NN generates updated trajectories that maximize the learned reward.

In yet another embodiment, a method is provided for the placement of unordered macros on a chip. An NN generates a first probability distribution of a macro-order action under a current state of the chip, where the macro-order action is to select a macro from an unordered set of macros to be placed on a chip. The NN further generates a second probability distribution of a positional action under the current state of the chip, where the positional action is to select a coordinate on the chip for placing the macro. The NN samples the macro-order action and the positional action based on the first probability distribution and the second probability distribution, respectively. The method further comprises updating a macro-order mask to remove the macro which has been placed from the unordered set, and updating a positional mask to block an area on the chip for subsequent placements of remaining macros.

Other aspects and features will become apparent to those ordinarily skilled in the art upon review of the following description of specific embodiments in conjunction with the accompanying figures.

### BRIEF DESCRIPTION OF THE DRAω INGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

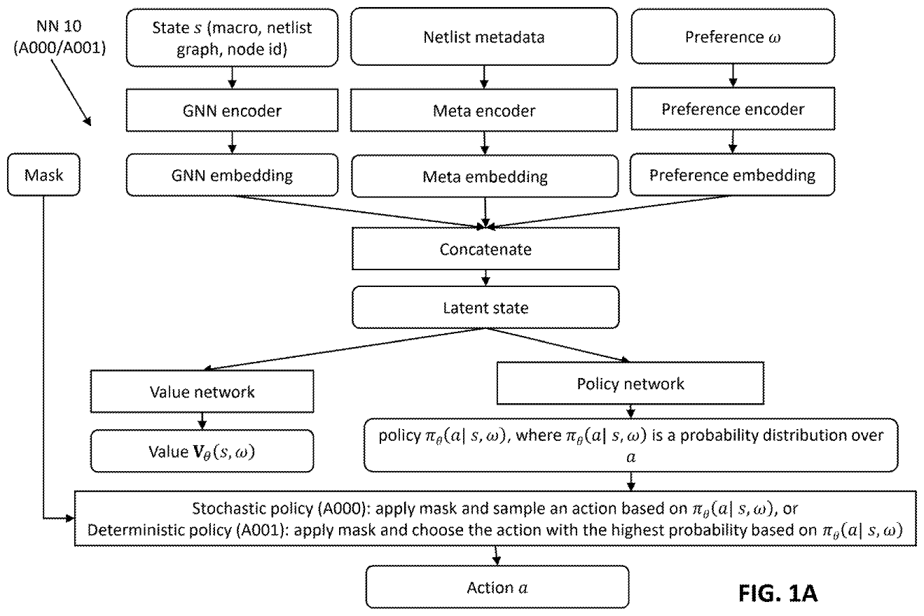

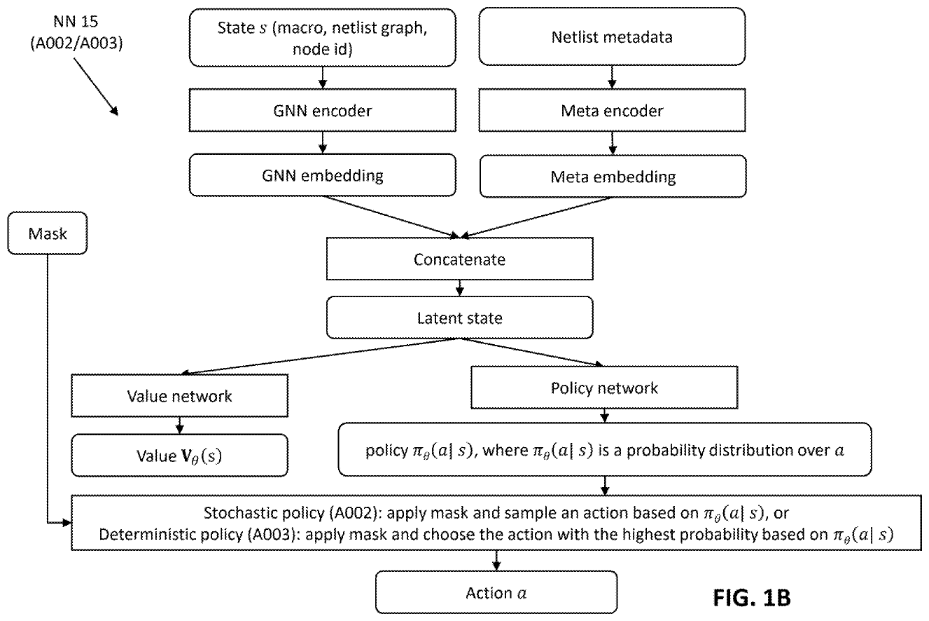

FIG. 1A is a block diagram illustrating a neural network (NN) for macro placement according to one embodiment.

FIG. 1B is a block diagram illustrating an NN for macro placement according to another embodiment.

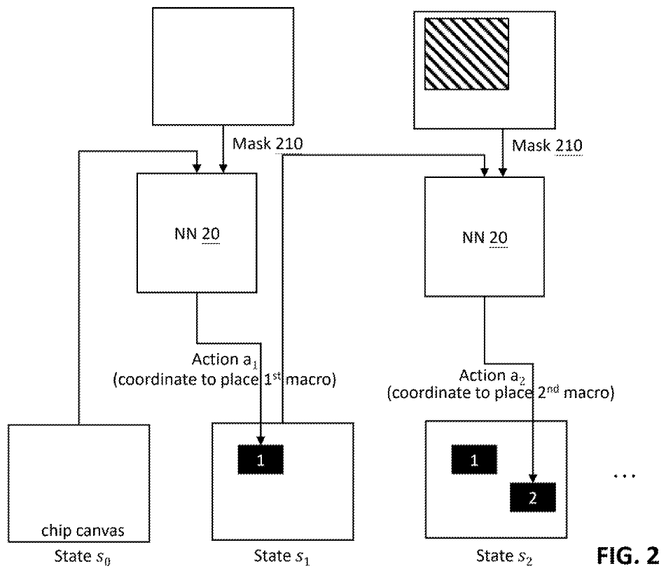

FIG. 2 illustrates a macro placement process according to one embodiment.

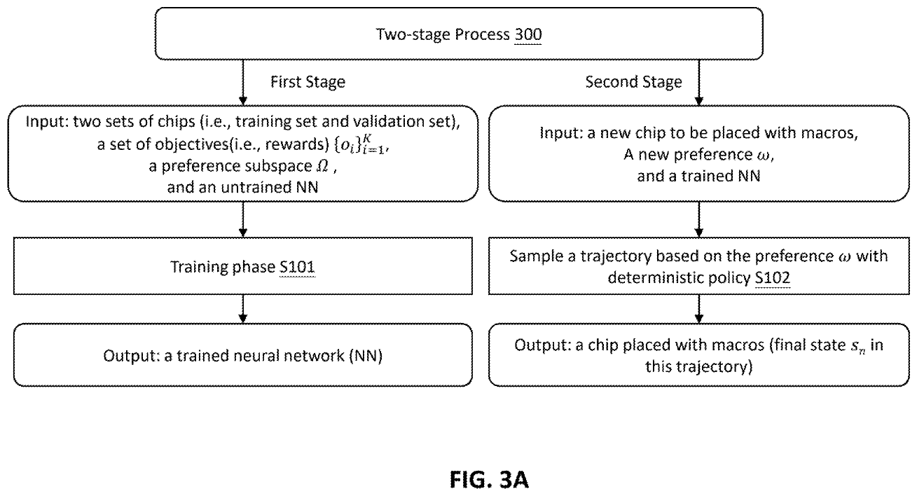

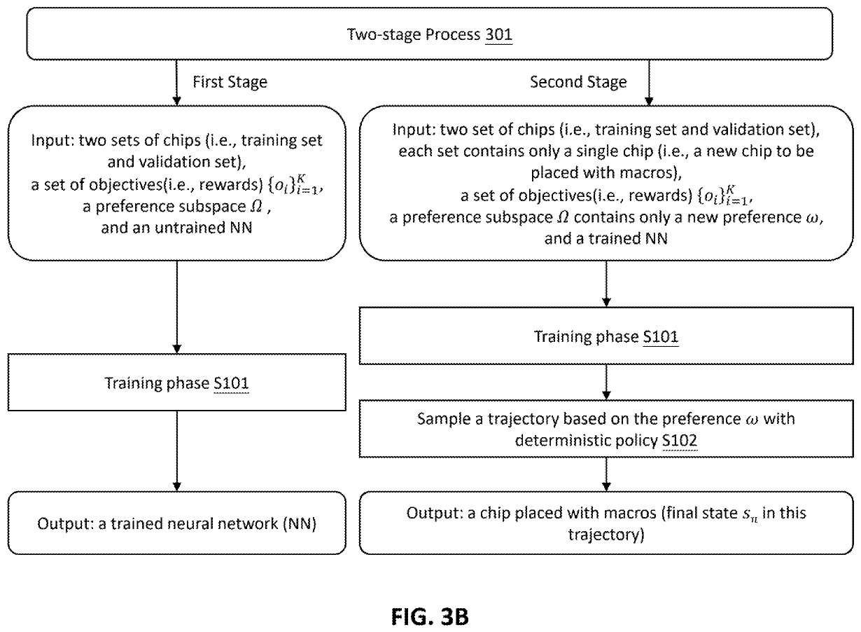

FIG. 3A is a flow diagram illustrating a two-stage process for macro placement according to one embodiment.

FIG. 3B is a flow diagram illustrating a two-stage process for macro placement according to another embodiment.

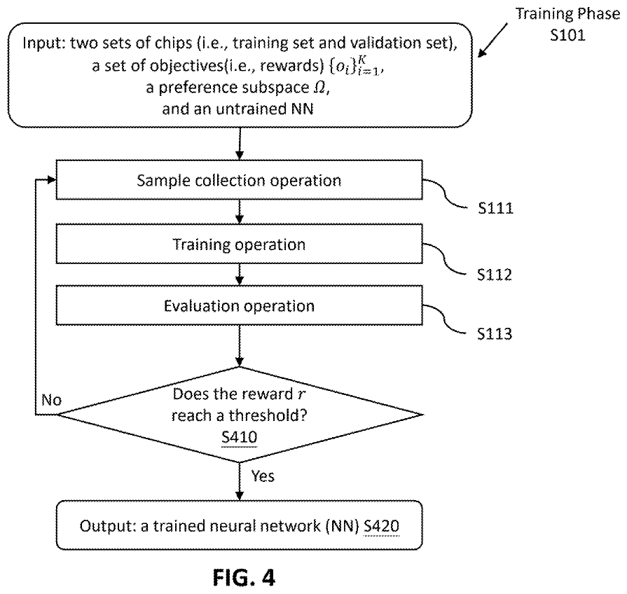

FIG. 4 is a flow diagram of a training phase (S101) in FIG. 3A and FIG. 3B according to one embodiment.

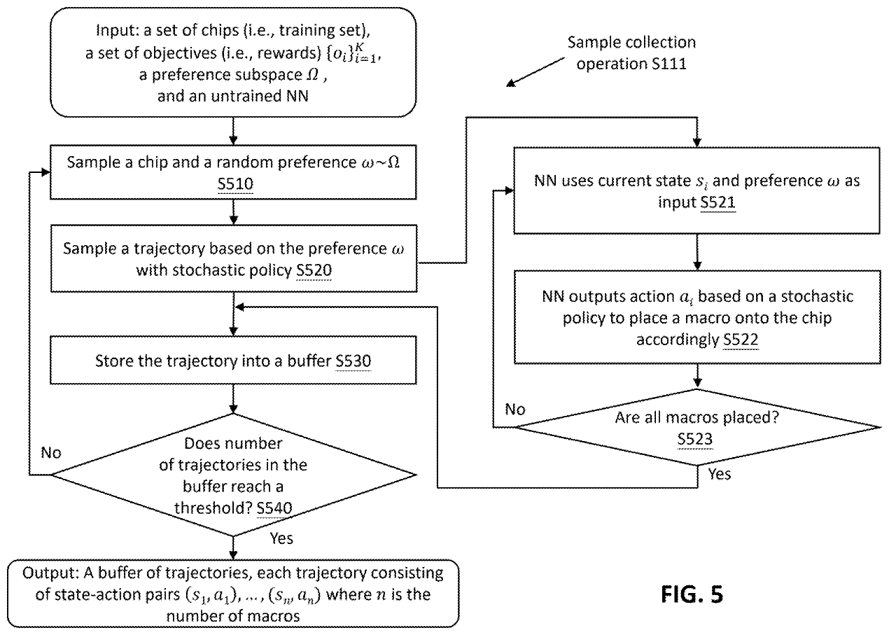

FIG. 5 is a flow diagram of a sample collection operation (S111) according to one embodiment.

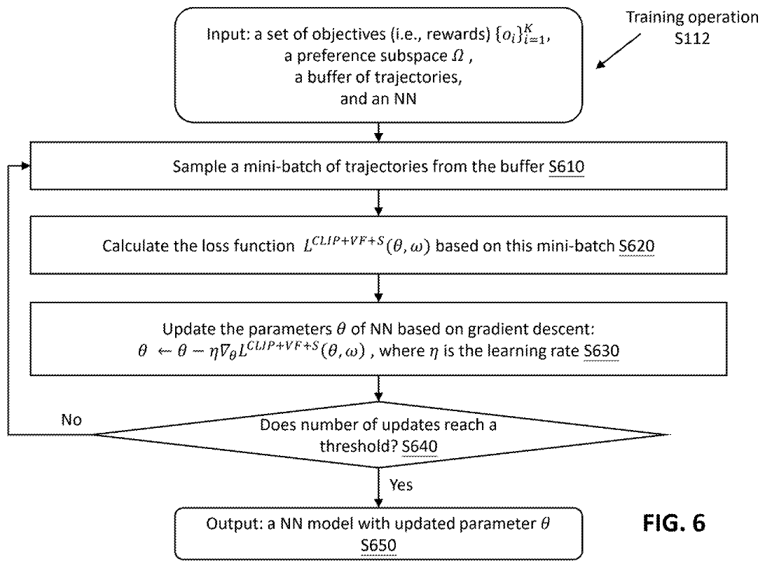

FIG. 6 is a flow diagram of a training operation (S112) according to one embodiment.

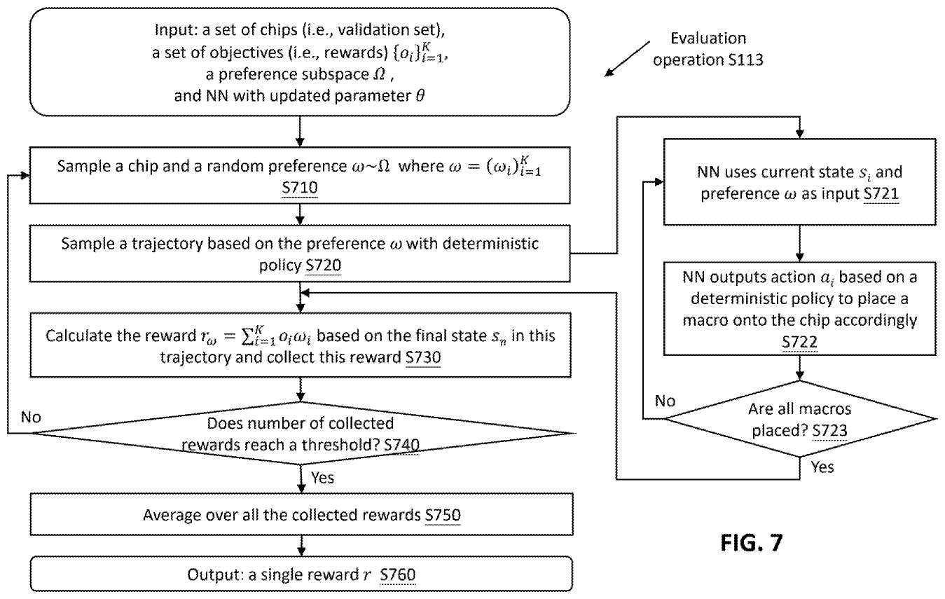

FIG. 7 is a flow diagram of an evaluation operation (S113) according to one embodiment.

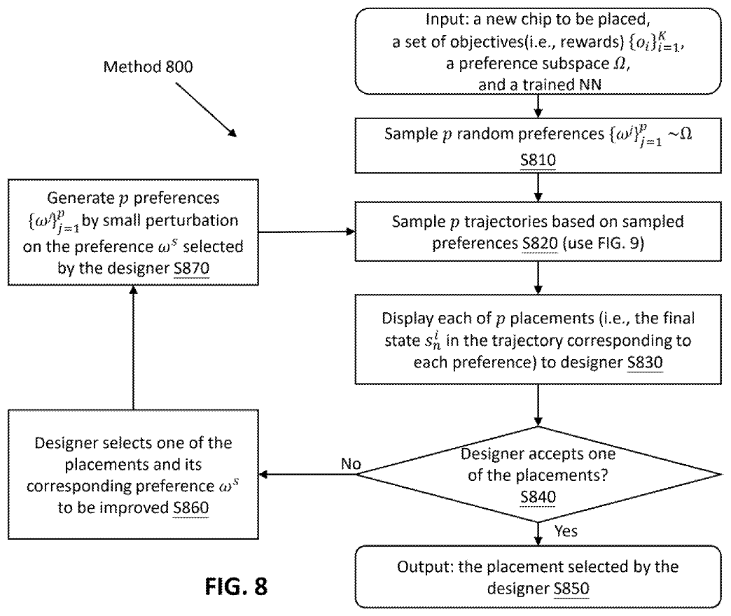

FIG. 8 is a flow diagram illustrating a macro placement method based on a designer's hints according to one embodiment.

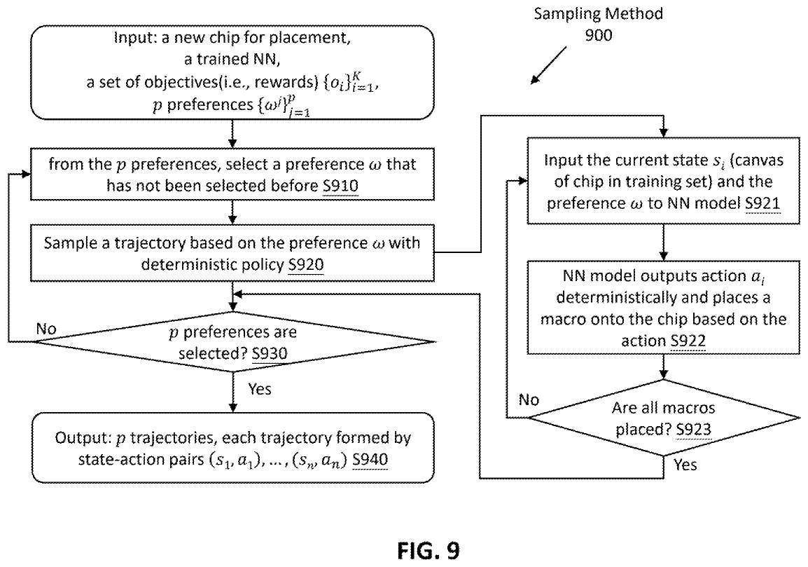

FIG. 9 is a flow diagram of a trajectory sampling method according to one embodiment.

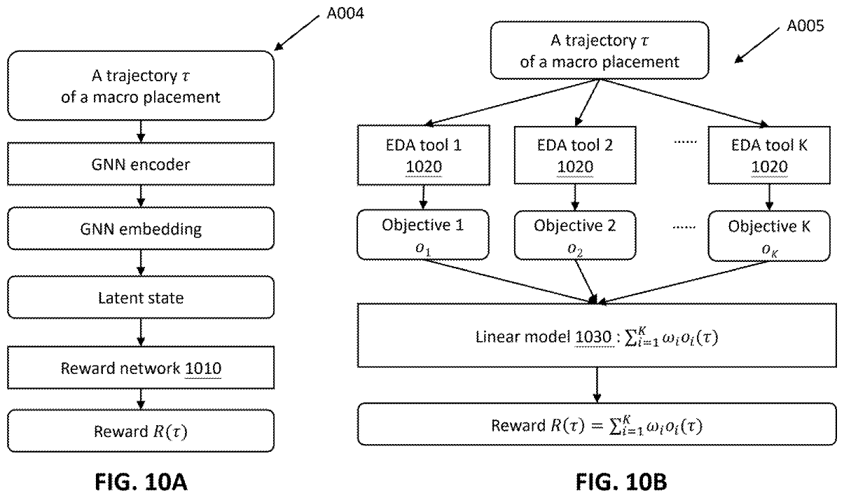

FIG. 10A is a block diagram of a reward-searching NN according to one embodiment.

FIG. 10B is a block diagram of a search tool according to one embodiment.

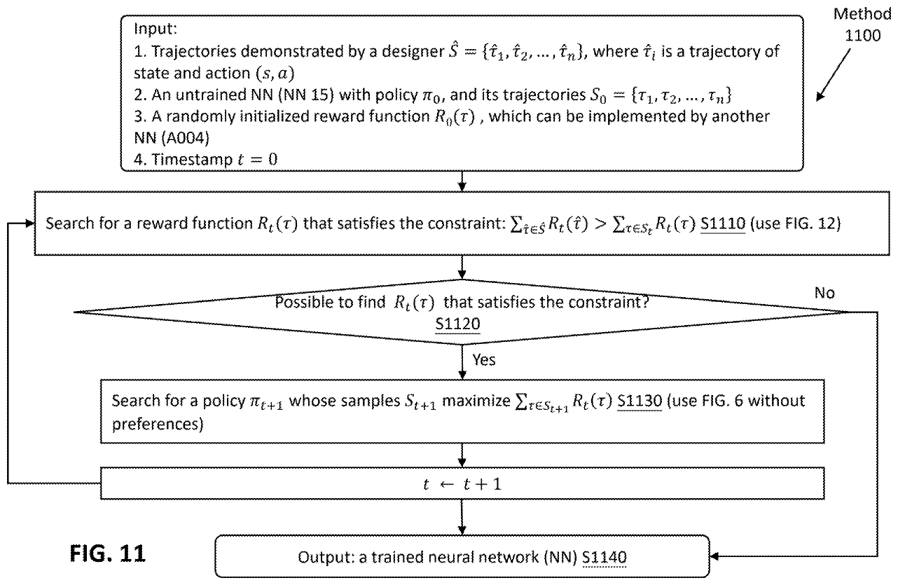

FIG. 11 is a flow diagram illustrating a method for training an NN to produce a macro placement according to one embodiment.

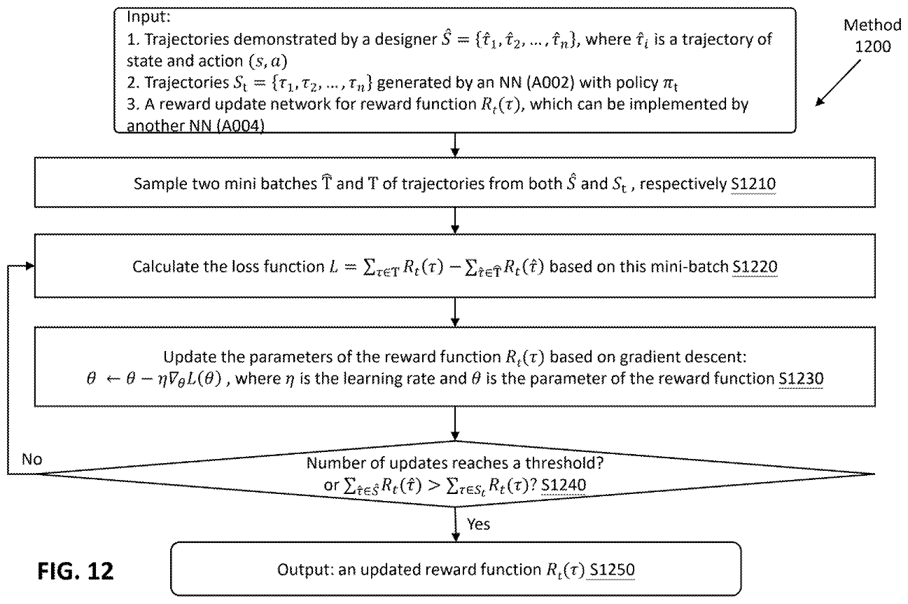

FIG. 12 is a flow diagram illustrating a method for updating a reward function according to one embodiment.

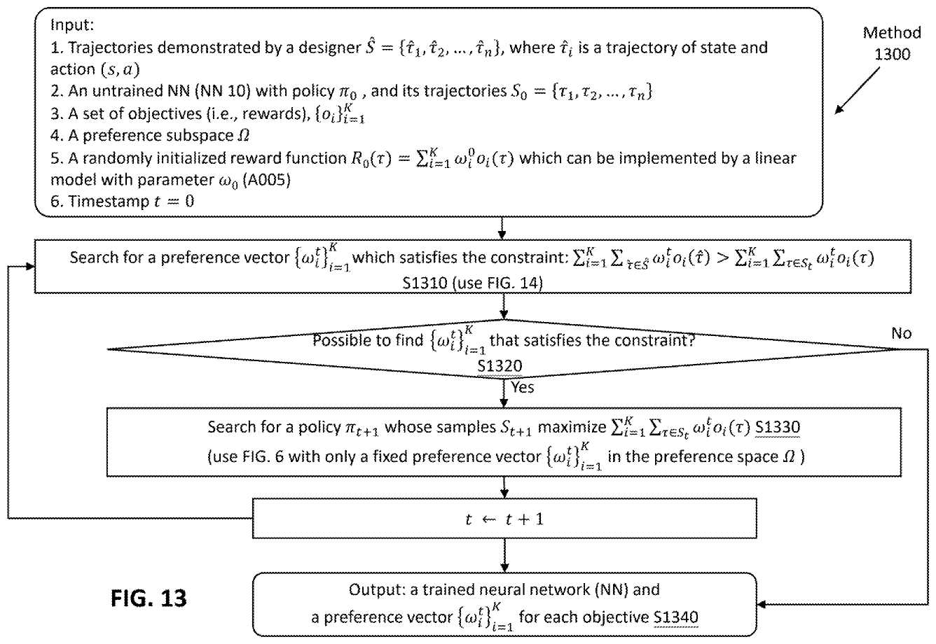

FIG. 13 is a flow diagram illustrating a method for training an NN to produce a macro placement according to another embodiment.

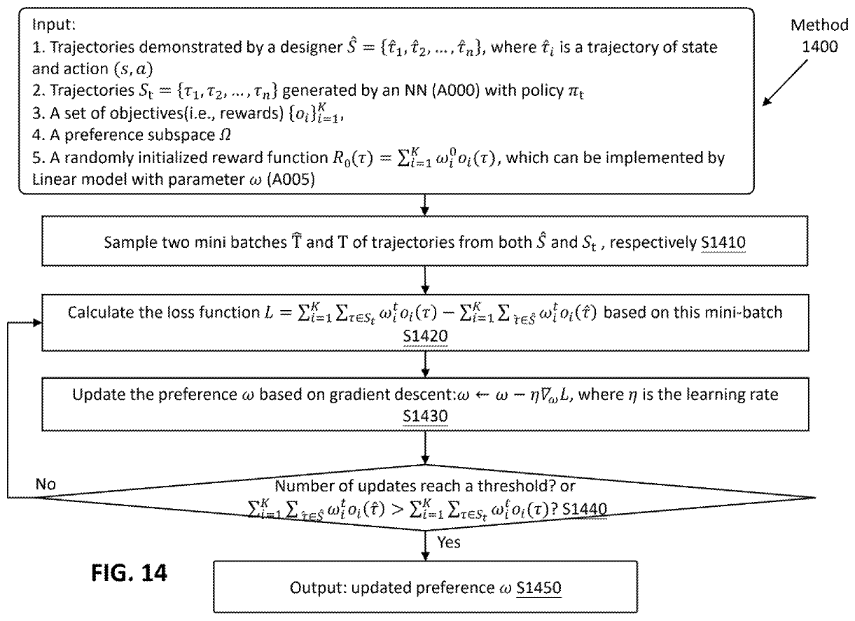

FIG. 14 is a flow diagram illustrating a method for updating a reward function according to another embodiment.

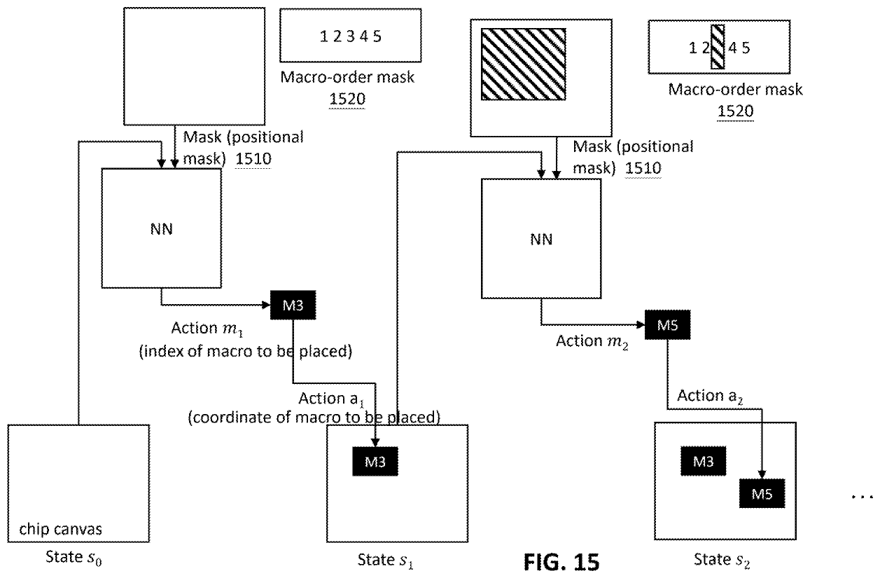

FIG. 15 is a diagram illustrating a macro placement process with a macro-order mask according to one embodiment.

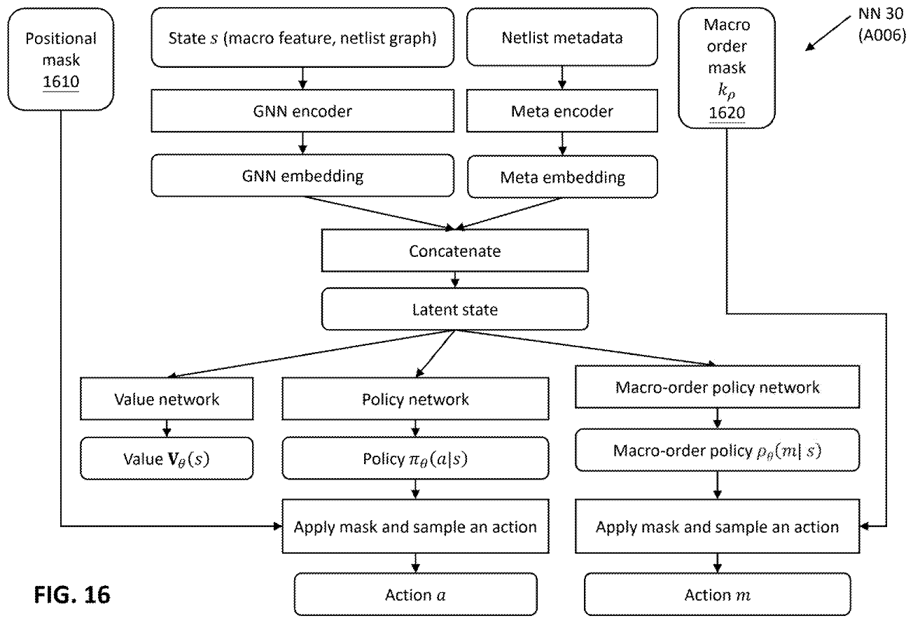

FIG. 16 is a block diagram illustrating an NN for placing unordered macros on a circuit block according to one embodiment.

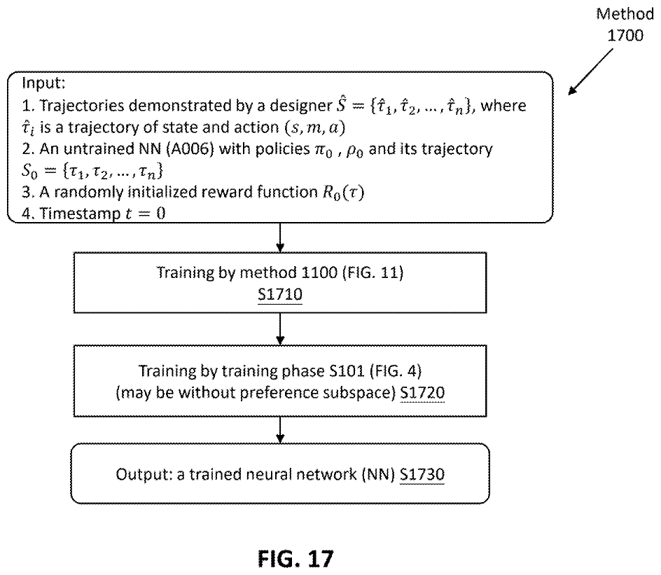

FIG. 17 is a flow diagram illustrating a method for training an NN to place unordered macros on a circuit block according to one embodiment.

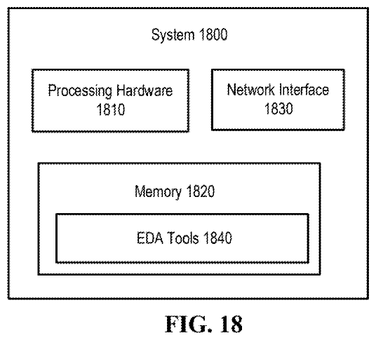

FIG. 18 illustrates an example of a system according to one embodiment.

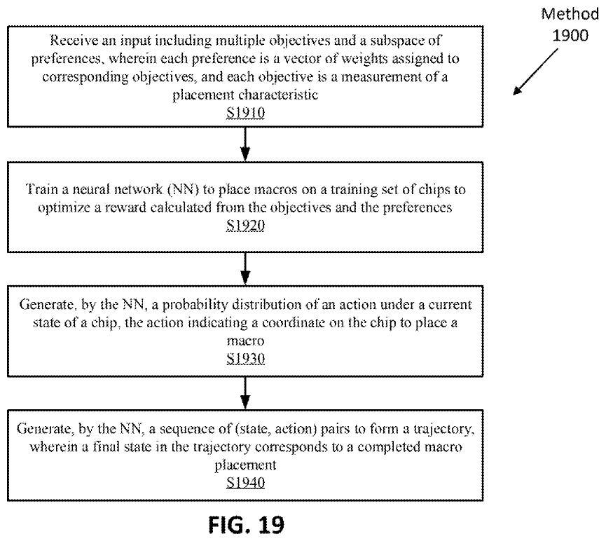

FIG. 19 is a flow diagram illustrating a method for macro placement by an NN according to one embodiment.

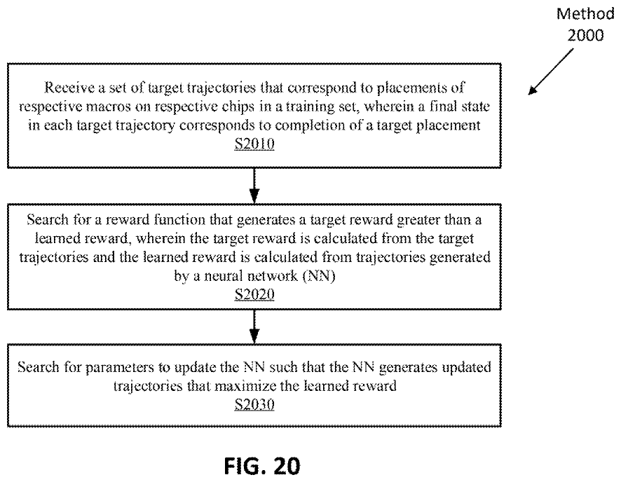

FIG. 20 is a flow diagram illustrating a method for training an NN to perform macro placement according to one embodiment.

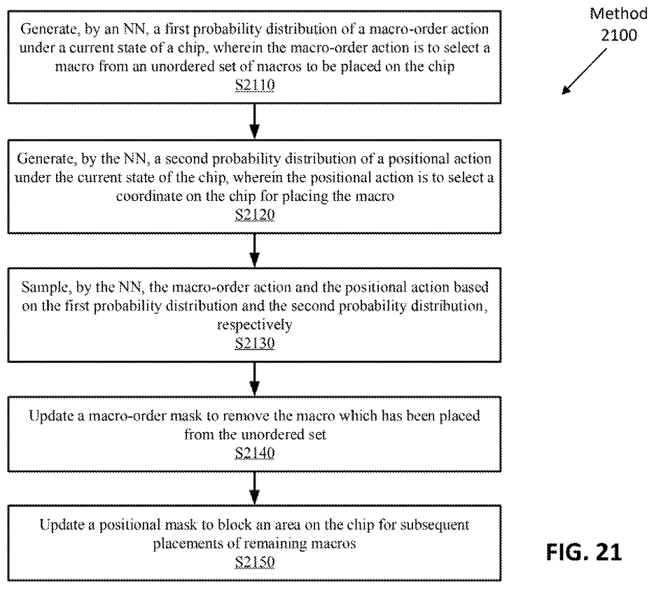

FIG. 21 is a flow diagram illustrating a method for placement of unordered macros according to one embodiment.

### DETAILED DESCRIPTION

In the following description, numerous specific details are set forth. However, it is understood that embodiments of the invention may be practiced without these specific details. In other instances, well-known circuits, structures, and techniques have not been shown in detail in order not to obscure the understanding of this description. It will be appreciated, however, by one skilled in the art, that the invention may be practiced without such specific details. Those of ordinary skill in the art, with the included descriptions, will be able to implement appropriate functionality without undue experimentation.

In this disclosure, a two-stage process for macro placement is described. In the first stage, the process takes in an untrained placement tool Z^{[0]} and a designer input ξ that includes a subspace Ω of design preferences and multiple objectives {oᵢ}ᵢ₌₁^{K} where K is the number of objectives, and produces an output EDA tool Z^{[ξ]}. This Z^{[ξ]} can take in a specific ω∈Ω to produce a corresponding output realization of macro placement. The first stage does not produce a placement; instead, it produces a “placement tool,” which can optimize multiple objectives. The first step is referred to as multi-objective learning. In the second stage, when design preferences are known with certainty, the tool Z^{[ξ]} is then invoked to find the placement for a given circuit block (also referred to as “chip”). This second stage is referred to as delayed final optimization. In one embodiment, the placement tool may be a neural network (NN) executed by a computing system.

The following description discloses a number of methods with reference to flow diagrams. These methods may be performed by a computing system, such as a system 1800 in FIG. 18, on which a placement tool such as an NN is trained. Moreover, some of the methods in the following descriptions refer to the use of a “threshold.” It is understood that the thresholds in different methods/stages/operations/steps may refer to different numerical values. As used herein, a semiconductor chip is an integrated circuit block also referred to as a chip. A macro contains a set of integrated circuit components, and a chip canvas is a two-dimensional (2D) area on the chip where macros may be placed.

FIG. 1A is a block diagram illustrating an NN 10 for macro placement according to one embodiment. NN 10 receives an input including state s (macro, netlist graph, node id), netlist metadata, and preference ω, each of which is encoded into a low-dimension vector called embedding. NN 10 concatenates these embedding vectors to represent a latent state. This latent state is fed into a value network and a policy network. The policy network generates a policy π_{θ}(a|s, ω), where π_{θ}(a|s, ω) is a probability distribution of action a in state s. The action specifies a coordinate on the canvas for placing a macro. The state is the canvas including any macros placed thereon. The value network generates a value that predicts the reward of action a. NN 10 is parameterized by θ, which represents the set of parameters that defines NN 10. Based on policy π_{θ}(a|s, ω), NN 10 applies a mask on the canvas and generates an action as output. The action is generated based on policy π_{θ}(a|s, ω), as well as a stochastic policy or a deterministic policy. In this disclosure, NN 10 following the stochastic policy is referred to as A000, and NN 10 following the deterministic policy is referred to as A001. In some embodiments, NN 10 may be used for macro placement.

FIG. 1B is a block diagram illustrating an NN 15 for macro placement according to another embodiment. The difference between NN 10 and NN 15 is that NN 15 does not receive preference ω as input. NN 15 applies a mask on the canvas and generates an action as output. The action is generated based on policy π_{θ}(a|s), as well as a stochastic policy or a deterministic policy. In this disclosure, NN following the stochastic policy is referred to as A002, and NN 15 following the deterministic policy is referred to as A003. In some embodiments, NN 15 may be used for macro placement.

FIG. 2 illustrates a macro placement process according to one embodiment. Given a chip canvas and a trained NN 20, NN 20 performs an action a₁ to place a macro 1 on a first coordinate of the canvas. For multi-objective macro placement, NN 20 may have the same network structure as NN 10 (FIG. 1A) or NN 15 (FIG. 1B). The state of the canvas at this point (after action a₁ is performed) is denoted as s₁. A mask 210 is updated to indicate the area surrounding macro 1 that is not to be occupied by the next macro. NN 20 then performs an action a₂ to place a macro 2 on a second coordinate of the unmasked portion of the canvas. The canvas state is updated to s₂, and mask 210 is also updated (not shown) to prevent subsequent macros from undesired overlapping with the first two macros. The chip placement process continues until all of the macros are placed on the chip canvas.

The chip placement process illustrated in FIG. 2 produces a trajectory of (state, action) pairs (s₁, a₁), . . . , (sₙ, aₙ) for placing n macros, where the final state sₙ denotes the chip canvas with completed macros placement. For a given state, NN 20 is trained to generate a probability distribution for a corresponding action. In one embodiment, NN 20 applies mask 210 to the probability distribution to produce a masked distribution over grid points on the chip canvas where an action can take place. With a deterministic policy, NN 20 chooses an action with the highest probability to place a macro according to the masked distribution. With a stochastic policy, NN 20 samples an action for placing a macro according to the masked distribution.

An example of a masked distribution is as follows. If the probability distribution generated by the policy network of NN 20 over 5 coordinates where actions can take place is:

| Action 1 | Action 2 | Action 3 | Action 4 | Action 5 |
|---|---|---|---|---|
| 0.2 | 0.3 | 0.1 | 0.1 | 0.3 |

Applying a mask that blocks out areas where actions 1, 2, and 4 can take place, this probability distribution becomes a masked distribution as follows:

| Action 1 | Action 2 | Action 3 | Action 4 | Action 5 |
|---|---|---|---|---|
| 0 | 0 | 0.1/(0.1 + | 0 | 0.3/(0.1 + |
| | | 0.3) = 0.25 | | 0.3) = 0.75 |

FIG. 3A is a flow diagram illustrating a two-stage process 300 for macro placement according to one embodiment. In FIG. 3A and the flow diagrams of subsequent figures, blocks with rounded corners represent input/output, and blocks with square corners represent operations.

In the first stage, a subspace of preferences is given but a designer's preference is unknown or undetermined. The first stage receives an input including two sets of chips (i.e., a training set and a validation set), a set of objectives (i.e., rewards) {oᵢ}ᵢ₌₁^{K}, a preference subspace Ω, and an untrained NN. The untrained NN may have the same network structure as NN 10 (FIG. 1A). A training phase is performed to produce an output of a trained NN (S101). In the second stage (also referred to as the delayed final optimization), the designer's preference is given. The second stage receives a new chip to be placed with macros, a new preference ω, and the trained NN. The trained NN samples a trajectory based on the new preference w with the deterministic policy (S102). The deterministic policy is described with reference to network A001 in FIG. 1A. The output of the second stage is the new chip placed with macros (i.e., the final state sₙ in the trajectory).

FIG. 3B is a flow diagram illustrating a two-stage process 301 for macro placement according to another embodiment. In the first stage, a subspace of preferences is given but a designer's preference is unknown or undetermined. The first stage is the same as the two-stage process 300 in FIG. 3A. The second stage (also referred to as the delayed final optimization) differs from the first stage in that the training set and the validation set each contain only a new chip to be placed with macros, and the preference subspace Ω contains only a new preference w which is the designer's preference. The NN trained in the first stage is further trained with the training phase (S101), and then samples a trajectory based on the new preference w with the deterministic policy (S102). The deterministic policy is described with reference to network A001 in FIG. 1A. The output of the second stage is the new chip placed with macros (i.e., the final state sₙ in the trajectory).

Before describing the details of the training phase (S101), it is helpful to provide examples of the objectives {oᵢ}ᵢ₌₁^{K} in the context of macro placement. An objective is a measurement of a placement characteristic. In one embodiment, the set of objectives {oᵢ}ᵢ₌₁^{K} may include WL(x), CWL(x), C(x), NS(x), which stand for the wirelength estimate, the critical path wirelength estimate, the congestion estimate, and the negative slack estimate for placement x, respectively. Another objective, power consumption estimate PWL(x), can be derived from the wirelength estimate. These objectives, other designer-specified metrics, and any other objectives relevant to the placement design (e.g., critical path timing) can be traded against each other using a multi-objective framework. The trade-off is represented by a preference ω, which is an array of preference values indicating weights assigned to corresponding objectives. An example of a composite objective is ω₁WL(x)+ω₂CWL(x)+ω₃ C(x), and a proper compromise among WL(x), CWL(x), C(x) depend at least on PWL(x) and NS(x).

In one embodiment, the set of objectives {oᵢ}ᵢ₌₁^{K} may further include a location objective. For example, when training Z^{[ξ]} (e.g., a neural network), the input may include information related to the canvas geometry and the intended positions of the macros. This information comes from physical constraints such as pins, I/O ports, preferred routing pathways, and preferred location of negative space for standard cell placement if such information is available to the designer. Note, however, that blockages on the canvas are handled by a mask, which is different from a location objective.

In one embodiment, a location objective may be modeled as positional anchors. Anchors are pairs of positional coordinates together with influence weights on the positions of selected macros. The influence of an anchor α on a macro m, denoted l(α, m), is a positive scalar function that can be computed from positional information alone.

A reward objective corresponding to the anchors is formed as a weighted sum:

Σ_{anchor α}Σ_{macro m}_{ᵢ} wᵢ^{α}l(α,mᵢ).

The anchors with only negative weights are referred to as negative anchors and the anchors with only positive weights are referred to as positive anchors. In the formulation of the reward objective above, by setting l(α, m)=0, anchors may be configured to influence only a subset of macros. In one embodiment, l(α, m)=d((x_{α}, y_{α}), (xₘ, yₘ)) for some distance function d, typically the L¹ or L² distance.

Additional location objectives may include the following. A positive anchor is used to attract certain macros toward the location of that anchor. Supposed that there is a positive anchor m. Macro i is connected to the anchor. An additional term ωₘ⁺dist(m, i) is added to the objective function. Given that it is to model an attractive force, ωₘ⁺ is negative. The location of the positive anchor is usually selected by a designer. A negative anchor is used to repel certain macros away from the location of that anchor.

Suppose that there is a negative anchor m. Macro j is connected to the anchor. An additional term ωₘ⁻dist(n, j) is added to the objective function. Given that it is to model a repelling force, ωₘ⁻ is positive. The location of the negative anchor is usually selected by a designer. A pin is where a wire penetrates the canvas boundary. A prospective pin is used when the location of that wire is not determined before placement. Thus, the location of a prospective pin is randomly chosen for each placement attempt among a number of choices. Once these choices are specified by the designer, the set of such choices is wrapped up in the vector of input parameters ξ which contributes to the training of the final EDA tool Z^{[ξ]} (e.g., a neural network).

Referring back to FIG. 3A and FIG. 3B, in one embodiment, the training phase (S101) is performed by a computing system to train an NN (e.g., NN 10 in FIG. 1A) to perform macro placement. The details of the training phase (S101) are described below with reference to FIG. 4-FIG. 7.

FIG. 4 is a flow diagram of the training phase (S101) in FIG. 3A and FIG. 3B according to one embodiment. The training phase begins when the computing system receives an input that includes a training set of chips, a validation set of chips, a set of objectives, a preference subspace, and an untrained NN. Each chip in the training set has a corresponding set of macros to be placed thereon. In one embodiment, the placement sequence of the macros for each chip is given; that is, the macros are ordered for the placement. An embodiment where macros are unordered for placement is described with reference to FIG. 15-FIG. 17.

The training phase includes three operations performed by the NN: a sample collection operation (S111), a training operation (S112), and an evaluation operation (S113). The training phase is completed when a reward (calculated in FIG. 7) reaches a predetermined threshold (S410). Otherwise, the three operations are repeated until the reward function reaches the threshold. The output of the training phase is a trained NN (S420) FIG. 5 is a flow diagram of the sample collection operation (S111) according to one embodiment.

In the sample collection operation, the NN samples a chip from the training set and randomly selects a preference from the preference subspace (S510). The NN also samples (i.e., generates) a trajectory based on the preference ω with the stochastic policy (S520). The stochastic policy is described with reference to network A000 in FIG. 1A. To generate a trajectory, the NN uses current state sᵢ and preference ω as input (S521). The NN outputs action aᵢ based on the stochastic policy to place a macro onto the sampled chip accordingly (S522). S521 and S522 are repeated until all of the macros are placed (S523), and a trajectory is formed by the sequence of (state, action) pairs. The trajectory is then stored in a buffer (S530). When the number of trajectories in the buffer reaches a threshold (S540), the buffer is provided as input to the training operation (S112) illustrated in FIG. 6.

FIG. 6 is a flow diagram of the training operation (S112) according to one embodiment. The input to the training operation (S112) includes a set of objectives (i.e., rewards) {oᵢ}ᵢ₌₁^{K}, a preference subspace Ω, a buffer of trajectories, and an NN (from FIG. 5). The trajectories in the buffer are generated in the sample collection operation (S111). The training operation begins with the NN sampling a mini-batch of trajectories from the buffer (S610). The NN calculates the loss function L^{CLIP+VF+S}(θ, ω) based on this mini-batch (S620), and updates the parameters θ of NN based on gradient descent (S630): θ←θ−η∇_{θ}L^{CLIP+VF+S}(θ, ω)), where η is the learning rate. S610, S620, and S630 are repeated until the number of updates reaches a predetermined threshold (S640). When the predetermined threshold is reached, the NN has the updated parameter θ (S650). As will be seen in the mathematical formulation below, the update to the parameters of the NN is based on a loss function that is a function of a preference ω and parameters θ.

The mathematical formulation of the training operation (S112) is provided below. The training operation (S112) can be formulated as a multi-objective Markov decision process (MOMDP), [symbol] , by which we mean an MDP with state space [symbol] and action space [symbol] and fixed transition dynamics, with a set of reward signals indexed by i, where reward (objective) signal i is denoted as oᵢ. The formulation also includes a preference parameter, ω, where ω=(ωᵢ)ᵢ₌₁^{K} is a K-dimensional vector. In the context of macro placement, the summarizing reward r_{ω}=Σᵢ₌₁^{K}oᵢωᵢ.

Both states and actions are indexed by ω as in (s; ω) and (a; ω) to denote the corresponding restriction to a standard IMDP. The restricted MDP is denoted as [symbol] ^{ω}. Also, the setting of episodic reinforcement learning (RL) is adopted herein, where there is a well-defined initial state, so independent of ω.

The NN parameter update can be calculated using the Proximal Policy Optimization (PPO) gradient estimator with generalized advantage estimation. For the application to the multi-objective macro placement problem, the loss function includes: A value function (s; θ), which receives the preference ω as input (i.e. v(s, ω; θ)). The value loss is computed across input states and values of w sampled from the buffer.

An entropy loss S[π_{θ}], which is an average of entropy values of the policy head across states, and can control the randomness of policy π_{θ}.

Specifically, the value function V^{π} output is a K-dimensional vector, such that

$${V}^{π} ( s , ω ) = 𝔼 [ {\sum }_{k = 0}^{∞} {γ}^{k} r ( {s}_{t + k} , π ( {s}_{t + k} , ω ) ) \vert {s}_{t} = s ]$$

A value net V_{θ}(s, ω) is used to represent the value function, and the estimated advantage within a given length-T trajectory can be written as:

$${\hat{A}}_{t} = {δ}_{t} + ( γλ ) {δ}_{t + 1} + … + {( γλ )}^{T - t + 1} {δ}_{T - 1} \\ where {δ}_{t} = {r}_{t} + γ {V}_{θ} ( {s}_{t + 1} , ω ) - {V}_{θ} ( {s}_{t} , ω )$$

We define the policy function as π_{θ}(aₜ|sₜ, ω), and define ρₜ(θ, ω)=π_{θ}(aₜ|sₜ,ω/π_{0ld}(aₜ|sₜ,ω), then the loss function becomes:

$${L}^{CLIP} ( θ , ω ) = {\hat{𝔼}}_{t} [ ( {ρ}_{t} ( θ , ω ) {ω}^{T} {\hat{A}}_{t} , clip ( {ρ}_{t} ( θ , ω ) , 1 - ϵ , 1 + ϵ ) {ω}^{T} {\hat{A}}_{t} ) ] \\ {L}^{CLIP + VF + S} ( θ , ω ) = {\hat{𝔼}}_{t} [ {L}_{t}^{CLIP} ( θ , ω ) - {c}_{1} {L}_{t}^{VF} ( θ , ω ) + {c}_{2} S [ {π}_{θ} ] ( {s}_{t} , ω ) ] , \\ where {L}_{t}^{VF} = \vert {ω}^{T} {V}_{θ} ( {s}_{t} , ω ) - {ω}^{T} {V}^{π} ( {s}_{t} , ω ) \vert .$$

During training, a new ω′ is found which can maximize the loss function

$${L}_{t}^{VF} ( θ , ω , {ω}^{′} ) = \vert {ω}^{T} {V}_{θ} ( {s}_{t} , {ω}^{′} ) - {ω}^{T} {V}^{π} ( {s}_{t} , {ω}^{′} ) \vert \\ {L}^{CLIP} ( θ , ω , {ω}^{′} ) = {\hat{𝔼}}_{t} [ ( {ρ}_{t} ( θ , {ω}^{′} ) {ω}^{T} {\hat{A}}_{t} , clip ( {ρ}_{t} ( θ , {ω}^{′} ) , 1 - ϵ , 1 + ϵ ) {ω}^{T} {\hat{A}}_{t} ) ] \\ {L}^{CLIP + VF + S} ( θ , ω ) = {max}_{ω ′ ∈ Ω} {\hat{𝔼}}_{t} [ {L}_{t}^{CLIP} ( θ , ω , {ω}^{′} ) - {c}_{1} {L}_{t}^{VF} ( θ , ω , {ω}^{′} ) + {c}_{2} S [ {π}_{θ} ] ( {s}_{t} , {ω}^{′} ) ]$$

This new ω′ is used to calculate L^{CLIP} (θ, ω, ω′) and Lₜ^{VF}(θ, ω, ω′) so that the policy of the neural network can be generalized to various ω′ and can avoid being misaligned with wrong preferences.

Finally, the update mechanism for the parameter θ is: θ←θ−η∇_{θ}L^{CLIP+VF+S}(θ, ω), which is the parameter update formula in S630 of the training operation (S112).

FIG. 7 is a flow diagram of the evaluation operation (S113) according to one embodiment. The input to the evaluation operation (S113) includes a set of chips (i.e., a validation set), a set of objectives (i.e., rewards) {oᵢ}ᵢ₌₁^{K}, a preference subspace Ω, and the NN with updated parameter θ (from FIG. 6). The evaluation operation (S113) begins with the NN samples a chip and a random preference ω˜Ω, where ω=(ωᵢ)ᵢ₌₁^{K} (S710). The NN samples (i.e., generates) a trajectory based on the preference ω with the deterministic policy (S720). The deterministic policy is described with reference to network A001 in FIG. 1A. To generate a trajectory, the NN uses current state sᵢ and preference ω as input (S721). The NN outputs action aᵢ based on the stochastic policy to place a macro onto the sampled chip accordingly (S722). S721 and S722 are repeated until all of the macros are placed (S723), and a trajectory is formed by the sequence of (state, action) pairs. The NN proceeds to calculate the reward r_{ω}=Σᵢ₌₁^{K}oᵢωᵢ based on the final state sₙ in this trajectory and collect this reward (S730). S710, S720 (including S721-S723), and S730 are repeated until the number of collected rewards has reached a predetermined threshold (S740). The NN then averages over all the collected rewards (S750) and outputs a single reward value (S760).

Referring back to FIG. 4, after the evaluation operation (S113), the single reward value is compared with a threshold (S410). The operations S111, S112, and S113 are repeated until the single reward value output from the evaluation operation (S113) reaches the threshold. At this point, the NN is trained (S420). The trained NN may be given an input that includes a new preference as well as a new chip and macros to be placed.

The following disclosure describes solutions for macro placement problems that have difficult-to-formulate objectives. Sometimes, after reviewing the macro placement outcome from a trained NN, a designer realizes that the placement does not meet the expectation. In such a case, a designer may opt to inject or modify hints to the NN. Guided by the hints, the NN may produce a more desirable placement result.

There are many situations in which it is too difficult for the designer to directly formulate a design intent with a suitable ω. For example, sometimes a designer wants to keep the placement similar to a previous tried-and-proven placement, even at the expense of some minor reduction of achieved objectives. It is very difficult to formulate an appropriate preference parameter ω that can facilitate the designer's intent. As another example, in a trial placement, the locations of the pins (i.e., the 2D coordinates where wires penetrate the periphery of the allocated placement area) are not yet known, although the designer roughly knows about this. In this case, a designer may provide a fuzzy notion of the pin locations as a hint. As yet another example, a designer may not be knowledgeable about the use of the preferences co.

In one embodiment, a trained NN may generate a number of placements and a designer may rank how desirable they are or select the best placement as a candidate for improvement. Based on the designer's response, the NN can search for the hidden designer preference and generate a placement satisfactory to the designer.

An example of a composite objective for macro placement is:

$${ω}_{1} WL ( x ) + {ω}_{2} CWL ( x ) + {ω}_{3} C ( x ) + {ω}_{4} {WL}^{+} ( x ) + {ω}_{5} {WL}^{-} ( x ) .$$

where WL⁺(x) and WL⁻(x) are the wirelengths due to positive anchors and negative anchors.

Suppose the preference values ω₄ and ω₅ are unknown. The NN can generate a number of trajectory samples to query a designer, and iteratively search for the proper value of ω₄ and ω₅ based on the designer's response. Methods for the parameter search are described with reference to FIG. 8 and FIG. 9.

FIG. 8 is a flow diagram illustrating a macro placement method 800 based on a designer's hints according to one embodiment. The input to method 800 includes a new chip to be placed with macros, a set of objectives (i.e., rewards) {oᵢ}ᵢ₌₁^{K}, a preference subspace Ω, and a trained NN. The NN may have the same network structure as NN 10 (FIG. 1A). In one embodiment, the NN may have been trained by methods disclosed with reference to FIG. 4-FIG. 7. The NN samples p random preferences {ω^{j}}ⱼ₌₁^{p} from the preference subspace Ω (S810) for the new chip. The NN further samples p trajectories based on the sampled preferences (S820). The trajectory sampling (S820) is further explained with reference to FIG. 9. The p trajectories correspond to p placements; each placement is the final state sₙ^{j} in each trajectory corresponding to one of the p preferences. The system shows (e.g., displays) the p placements to the designer (S830). The designer may accept one of the placements (S840), and method 800 terminates with the accepted placement as output (S850). If the designer accepts none of the p placements, the designer may select one of the placements and its corresponding preference ω^{s} to be improved (S860). The selected placement may be the closest to the designer's hidden preference. The NN then generates another p preferences {ω^{j}}ⱼ₌₁^{p} by a small perturbation in the preference ω^{s} selected by the designer (S870). For example, a script may modify one or more preference values ω^{j} in ω^{a} by respective one or more delta values, where each delta value is in a predetermined value range (e.g., within the range of +/−ε). S820, S830, and S840 are repeated until the designer accepts one of the placements generated by the NN. The preference corresponding to the accepted placement is the designer's hidden preference.

FIG. 9 is a flow diagram of a trajectory sampling method 900 according to one embodiment. The NN performs method 900 as part of S820 in FIG. 8. The input to method 900 includes a new chip for placement, a trained NN, a set of objectives (i.e., rewards) {oᵢ}ᵢ₌₁^{K}, p preferences {ω^{j}}ⱼ₌₁^{p}. From the p preferences, the NN selects a preference ω that has not been selected before (S910). The NN then samples a trajectory based on the selected preference ω with the deterministic policy (S920). The deterministic policy is described with reference A001 in FIG. 1A. The trajectory sampling further includes inputting the current state sᵢ (i.e., the canvas of the chip) and the preference ω to the NN (S921), and the NN outputs action aᵢ deterministically and places a macro onto the chip based on the action (S922). S921 and S922 are repeated until all of the macros are placed on the chip (S923). S910 and S920 (as well as S921-S923) are repeated until p preferences are selected (S930), which means that p corresponding trajectories are generated. The NN outputs the p trajectories, each trajectory is formed by state-action pairs (s₁, a₁), . . . , (sₙ, aₙ) (S940).

Another approach to difficult-to-formulate objectives is a mechanism that infers a hidden reward function via inverse reinforcement learning. The mechanism is based on a designer's demonstration of placement samples. With this approach, a learner (e.g., an AI agent) tries to learn the hidden reward mechanism of a demonstrator. The training data is the demonstrated trajectories, also referred to as the target trajectories Ŝ={\hat{τ}₁, \hat{τ}₂, . . . , \hat{τ}ₙ}, where each \hat{τ}ᵢ is a trajectory of a placement sample. Given these target trajectories, the AI agent searches for the hidden reward function R(\hat{τ}). In one embodiment, the AI agent is an NN. The AI agent may be trained on a computing system, such as system 1800 in FIG. 18.

FIG. 10A is a block diagram of a reward-searching NN (referred to as A004) used by the AI agent to search for a reward function according to one embodiment. Given an input including a trajectory τ of a macro placement, the reward-searching NN applies a graph neural network (GNN) to encode and embed τ into a latent state. The reward-searching NN includes a reward network 1010, which processes the latent state and outputs a reward R (τ). The reward-searching operations of the reward-searching NN are described with reference to FIG. 12.

FIG. 10B is a block diagram of a search tool A005 used by the AI agent to search for a reward function according to one embodiment. In this example, a set of objectives is obtained by electronic design automation (EDA) tools 1020. Each EDA tool 1020 calculates one objective (e.g., wirelength, timing, or density of the macros to be placed on a chip). After the objectives are calculated, a linear model 1030 with weights (i.e., preference) ω calculates a linear combination of the weights and the objectives, and outputs the calculated linear combination as a reward R(τ). The reward is used iteratively to update the parameters of the AI agent, which may be an untrained NN such as A000 in FIG. 1A or A002 in FIG. 1B in some embodiments. The operations of the linear model 1030 are described with reference to FIG. 14.

FIG. 11 is a flow diagram illustrating a method 1100 for training an NN to produce a macro placement according to one embodiment. The NN may be NN 15 in FIG. 1B. Method 1100 follows the framework of a Generative Adversarial Network, in which the policy w is the generator, and the reward function R (τ) is the discriminator.

At time T=0, the NN with policy π₀ is randomly initialized to produce trajectories S₀={τ₁, τ₂, . . . , τₙ}, and a reward function R₀(τ) is randomly initialized. At time T=t, the system first searches for a reward function Rₜ (τ) that satisfies the constraint: Σ_{\hat{τ}∈Ŝ}Rₜ(\hat{τ})>Σ_{τ∈S}_{ₜ}Rₜ (τ) (S1110), since Ŝ is the set of golden samples. The reward Σ_{\hat{τ}∈Ŝ}Rₜ(\hat{τ}) is referred to as the target reward, and Σ_{τ∈S}_{ₜ}Rₜ (τ) is referred to as the learned reward. The reward search may be performed by another NN such as A004 in FIG. 10A using a method 1200 illustrated in FIG. 12. If an Rₜ(τ) that satisfies the constraint can be found (S1120), the NN proceeds to search for a policy πₜ₊₁ whose samples (i.e., trajectories) Sₜ₊₁ maximize Σ_{τ∈S}_{ₜ}Rₜ (τ) (S1130). The policy search may be performed by the NN using the training operation illustrated in FIG. 6 but without preference ω. S1110-S1130 are repeated until it is not possible (e.g., within a time limit) to find a reward function Rₜ(τ) that satisfies Σ_{\hat{τ}∈Ŝ}Rₜ(\hat{τ})>Σ_{τ∈S}_{ₜ}Rₜ (τ). At this point, the NN's policy πₜ is indistinguishable from that of the demonstrator \hat{π}. In other words, the NN is able to mimic the demonstrator's behavior indistinguishably. Method 1100 terminates and outputs a trained NN (S1140).

FIG. 12 is a flow diagram illustrating a method 1200 for updating a reward function according to one embodiment. The reward search at S1120 (FIG. 11) can be performed by iteratively updating the reward function. The input to method 1200 includes: the demonstrated trajectories Ŝ={\hat{τ}₁, \hat{τ}₂, . . . , \hat{τ}ₙ}, where \hat{τ}ᵢ is a trajectory of state and action (s, a), the trajectories Sₜ={τ₁, τ₂, . . . , τₙ} generated by the NN from FIG. 11 (A002) with policy πₜ, and a reward update network for reward function Rₜ(τ), which may be implemented by another NN such as A004 in FIG. 10A.

Method 1200 starts with the reward update network sampling two mini batches \hat{T} and T of trajectories from both Ŝ and Sₜ, respectively (S1210). The reward update network calculates the loss function L=Σ_{τ∈T}Rₜ(τ)−Σ_{\hat{τ}∈\hat{T}}Rₜ (\hat{τ}) based on this mini-batch (S1220). The reward update network updates the parameters of the reward function Rₜ(τ) based on gradient descent: θ←θ−η∇_{θ}L(θ), where η is the learning rate and θ is the parameter of the reward function (S1230). S1220 and S1230 are repeated until the number of updates reaches a threshold, or Σ_{\hat{τ}∈Ŝ}Rₜ(\hat{τ})>Σ_{τ∈S}_{ₜ}Rₜ (τ) (S1240). The output of method 1200 is an updated reward function Rₜ (τ) (S1250).

Inverse reinforcement learning can also be used to infer the unknown preference values ωᵢ of each objective oᵢ. In one embodiment, the reward function is a linear combination of preference values and the corresponding objectives: R(τ)=Σᵢ₌₁^{K}ωᵢoᵢ(τ), and Σ_{\hat{τ}∈Ŝ}Rₜ(\hat{τ})>Σ_{τ∈S}_{ₜ}Rₜ (τ) is the constraint for searching for new ωᵢ. When the learning halts (i.e., no R(τ) can satisfy Σ_{\hat{τ}∈Ŝ}Rₜ(\hat{τ})>Σ_{τ∈S}_{ₜ}Rₜ (τ), the output is the desired preference ωᵢ of each objective.

FIG. 13 is a flow diagram illustrating a method 1300 for training an NN to produce a macro placement according to another embodiment. The NN may be NN 10 in FIG. 1A. The input to method 1300 includes a preference subspace Ω and a set of objectives {oᵢ}ᵢ₌₁^{K}, in addition to all of the inputs to method 1100 (FIG. 11). Furthermore, the reward function in method 1300 is a linear combination of objectives and the corresponding preference values; i.e., reward function R(τ)=Σᵢ₌₁^{K}ωᵢoᵢ(τ). In one embodiment, the reward function may be updated by the search tool A005 (FIG. 10B), which uses the linear model 1030 to calculate the reward function.

At time T=t, the system first searches for a preference vector {ωᵢ^{t}}ᵢ₌₁^{K} that satisfies the constraint: Σᵢ₌₁^{K}Σ_{\hat{τ}∈Ŝ}ωᵢ^{t}oᵢ(\hat{τ})>Σᵢ₌₁^{K}Σ_{τ∈S}_{ₜ}ωᵢ^{t}oᵢ(τ) (S1310). If a preference vector {ωᵢ^{t}}ᵢ₌₁^{K} can be found that satisfies the constraint (S1320), the NN proceeds to search for a policy πₜ₊₁ whose samples (i.e., trajectories) Sₜ₊₁ maximize Σᵢ₌₁^{K}Σ_{τ∈S}_{ₜ}ωᵢ^{t}oᵢ(τ) (S1330). The preference search may be performed by a search tool such as A005 in FIG. 10B using a method 1400 illustrated in FIG. 14. The policy search may be performed by the NN using the training operation illustrated in FIG. 6 but with only a fixed preference vector {ωᵢ^{t}}ᵢ₌₁^{K} in the preference space Ω. S1310-S1330 are repeated until it is not possible (e.g., within a time limit) to satisfy the constraint of S1320. At this point, method 1300 terminates and outputs a trained NN, as well as a preference vector {ωᵢ^{t}}ᵢ₌₁^{K} for the set of objectives in the input (S1340).

FIG. 14 is a flow diagram illustrating a method 1400 for updating a reward function according to another embodiment. The reward search at S1320 (FIG. 13) can be performed by iteratively updating the preference. The input to method 1400 includes the preference subspace Ω and the set of objectives {oᵢ}ᵢ₌₁^{K}, in addition to all of the inputs to method 1200 (FIG. 12). Furthermore, the reward function in method 1400 is a linear combination of objectives and the corresponding preference values; i.e., reward function R(τ)=Σᵢ₌₁^{K}ωᵢoᵢ(τ). In one embodiment, the preference may be updated by the search tool A005 (FIG. 10B), which uses the linear model 1030 to calculate the reward function.

Method 1400 starts with the search tool sampling two mini batches \hat{T} and T of trajectories from both Ŝ and Sₜ, respectively (S1410). The search tool calculates the loss function L=Σᵢ₌₁^{K}Σ_{τ∈S}_{ₜ}ωᵢ^{t}oᵢ(τ)−Σᵢ₌₁^{K}Σ_{\hat{τ}∈Ŝ}ωᵢ^{t}oᵢ(\hat{τ}) based on this mini-batch (S1420). The search tool updates the parameters of w based on gradient descent: ω←ω−η∇_{ω}L, where η is the learning rate (S1430). S1420 and S1430 are repeated until the number of updates reaches a threshold, or Σᵢ₌₁^{K}Σ_{\hat{τ}∈Ŝ}ωᵢ^{t}oᵢ(\hat{τ})>Σᵢ₌₁^{K}Σ_{τ∈S}_{ₜ}ωᵢ^{t}oᵢ(τ) (S1440). The output of method 1400 is an updated preference ω (S1450). The reward function can be obtained by a combination of the updated preference and the objectives.

The following disclosure describes solutions for determining a sequential placement order for macro placement. Typically, a macro placement makes use of a fixed macro placement order, which is often determined by human experts according to a set of heuristics. If an arbitrary order is chosen, the speed of training an NN may be inferior to the order given by the heuristics.

A method is disclosed herein to improve the determination of placement orders. A neural network can be trained to learn a macro-ordering policy ρ simultaneously with the updates to a placement policy π. That is, the macros to be placed on a given chip are unordered. The NN may be trained with multiple random macro orders, and the experience can be collected for updating π. In ablation studies, it is noted that the convergence of w may be unaffected by the macro ordering, but the convergence speed can be affected adversely by certain suboptimal macro orders. It is also noted that a trained NN can perform well with a macro-ordering policy ρ that is not fully optimized.

In one embodiment, the policy ρ is parametrized by a neural network (e.g., A006 in FIG. 16), which takes as input the GNN representation of the canvas state s, as well as the GNN embeddings of all nodes. The action space is a discrete action space with each index corresponding to a particular node, and the policy outputs a softmax over these choices. A separate mask k_{ρ} eliminates choices for previously placed macros from the action space.

The macro-ordering policy ρ may have the same objective(s) and the same reward as π, and can benefit from the same buffer collection procedure and value functions as described above with reference to the training phase S101 in FIG. 3A and FIG. 4.

FIG. 15 is a diagram illustrating a macro placement process with a macro-order mask 1520 according to one embodiment. Given a chip canvas and a trained NN, the NN performs action m₁ to determine a first macro (e.g., M3) to be placed, and action a₁ to place M3 on a first coordinate of the canvas. The state of the canvas at this point (after actions m₁ and a₁ are performed) is denoted as s₁. Macro-order mask 1520 is updated to mask off the macro (M3) that has already been placed, and a mask 1510 is updated to indicate the area surrounding M3 that is not to be occupied by the next macro. Mask 1510 is also referred to as a positional mask. The NN then performs action m₂ to determine a second macro (e.g., M5) to be placed, and action a₂ to place M5 on a second coordinate of the unmasked portion of the canvas. The canvas state is updated to s₂, and both masks 1510 and 1520 are also updated (not shown). The macro placement process continues until all of the macros are placed on the canvas.

FIG. 16 is a block diagram illustrating an NN 30 for placing unordered macros on a circuit block according to one embodiment. NN 30 is also referred to as A006. To generate an action, NN 30 receives an input including state s (macro, netlist graph, node id) and netlist metadata, each of which is encoded into a low-dimension vector called embedding. NN 30 concatenates the embedding vectors to represent a latent state. This latent state is fed into a value network, a policy network, and a macro-order network. The policy network generates a policy π_{θ}(a|s), where π_{θ}(a|s) is a probability distribution over action a. The value network generates a value that predicts the reward of action a. The macro-order network generates a policy ρ_{θ}(a|s), where ρ_{θ}(a|s) is a probability distribution over action m. According to the policies π_{θ} and ρ_{θ}, NN 30 applies a positional mask 1610 on the canvas to block off areas taken by the already-placed macros, a macro-order mask 1620 on the already-placed macros, and determines the next actions a and m as output. The output actions may be determined stochastically.

The policies p and w may be trained simultaneously based on the experience collected in the same buffer of trajectories and the same reward signal. To overcome the cold start problem of multi-agent system dynamics (e.g., agents get collectively stuck in a non-improving recursive loop), the weights of p can be initialized via imitation learning from a set of heuristics.

FIG. 17 is a flow diagram illustrating a method 1700 for training an NN to place unordered macros on a circuit block according to one embodiment. The input includes a trajectory demonstrated by a designer Ŝ={\hat{τ}₁, \hat{τ}₂, . . . , \hat{τ}ₙ}, where fᵢ is a trajectory of state and action (s, m, a); an untrained NN (e.g., A006 in FIG. 16) with policy π₀ and ρ₀ and its trajectory S₀={τ₁, τ₂, . . . , τₙ}; a randomly initialized reward function R₀(τ); and timestamp t=0. The NN is trained by method 1100 of FIG. 11 (S1710), where policies π_{θ} and ρ_{θ} are simultaneously searched. The NN is further trained by the training phase S101 of FIG. 4 (S1720), where policies π_{θ} and ρθ are simultaneously trained. In some scenarios, the input may also include a preference subspace and a set of objectives. In other scenarios where the preference subspace is not an input, the sampling of the preference subspace can be skipped in the training phase S101. The output of method 1700 is a trained NN (S1730). The trained NN operates according to the policies π_{θ} and ρ_{θ} to determine, for each step in a trajectory, an action m for selecting a macro for placement, and an action a for selecting a coordinate for placing the selected macro.

FIG. 18 illustrates an example of a system 1800 according to one embodiment. System 1800 includes processing hardware 1810, a memory 1820, and a network interface 1830. In one embodiment, processing hardware 1810 may include one or more processors and accelerators, such as one or more of a central processing unit (CPU), a GPU, a digital processing unit (DSP), an AI processor, a tensor processor, a neural processor, a multimedia processor, other general-purpose and/or special-purpose processing circuitry.

System 1800 further includes the memory 1820 coupled to processing hardware 1810. Memory 1820 may include memory devices such as dynamic random access memory (DRAM), SRAM, flash memory, and other non-transitory machine-readable storage media; e.g., volatile or non-volatile memory devices. Memory 1820 may further include storage devices, for example, any type of solid-state or magnetic storage device. In one embodiment, memory 1820 may store one or more EDA tools 1840 including but not limited to neural networks, AI agents, and other tools for macro placement. Examples of EDA tools 1840 include A000 and A001 (FIG. 1A), A002 and A003 (FIG. 1B), A004 (FIG. 10A), A005 (FIG. 10B), and A006 (FIG. 16). In some embodiments, memory 1820 may store instructions which, when executed by processing hardware 1810, cause the processing hardware to perform the aforementioned methods and operations for macro placement and/or for training an NN to perform macro placement. However, it should be understood that the aforementioned methods and operations can be performed by embodiments other than the embodiments of A000 and A001 (FIG. 1A), A002 and A003 (FIG. 1B), A004 (FIG. 10A), A005 (FIG. 10B), and A006 (FIG. 16).

In some embodiments, system 1800 may also include a network interface 1830 to connect to a wired and/or wireless network. It is understood that the embodiment of FIG. 18 is simplified for illustration purposes. Additional hardware components may be included.

FIG. 19 is a flow diagram illustrating a method 1900 for macro placement by an NN according to one embodiment. Method 1900 may be performed by system 1800 in FIG. 18. Method 1900 begins with the system receiving an input including multiple objectives and a subspace of preferences (S1910). Each preference is a vector of weights assigned to corresponding objectives, and each objective is a measurement of a placement characteristic. The NN is trained to place macros on a training set of chips to optimize a reward calculated from the objectives and the preferences (S1920). The NN generates a probability distribution of an action under a current state of a chip, the action indicating a coordinate on the chip to place a macro (S1930). The NN further generates a sequence of (state, action) pairs to form a trajectory (S1940). The final state in the trajectory corresponds to a completed macro placement.

In one embodiment, the method of training the NN includes encoding a sampled preference from the subspace into a latent state of the NN. The reward may be calculated from a linear combination of a sampled preference from the subspace and the corresponding objectives.

The system applies a mask to block off areas on the chip. Applying this mask to the probability distribution produces a masked distribution over the chip. In one embodiment based on a stochastic policy, the NN samples the action according to the masked distribution. The NN further samples a set of trajectories in a sample collection operation according to the stochastic policy, and the system uses the set of trajectories to calculate an update to the parameters of the NN. In another embodiment based on a deterministic policy, the NN chooses the action with the highest probability according to the masked distribution. The NN samples a set of trajectories in an evaluation operation according to the deterministic policy. The system then calculates a final reward value from multiple reward values, and each reward value is calculated based on a final state of one of the trajectories.

In one embodiment, after training the NN, the system receives a given preference and a given chip on which macros are to be placed. The system further trains the NN with the given preference and stochastically sampled trajectories on the given chip. Then a final trajectory is sampled using the further-trained NN to generate the completed macro placement.

In one embodiment, the objectives include a distance to at least one of a positive anchor and a negative anchor. The positive anchor attracts the placement of a first subset of the macros and the negative anchor repels the placement of a second subset of the macros.

In one embodiment, the system may use the NN to generate a set of placements to place the same set of macros on a given chip, and each placement is generated based on a different preference. The system then receives an indication of a candidate placement among the set of placements. The candidate placement is generated based on a candidate preference. The system modifies the candidate preference to generate p preferences. The NN then generates a subsequent set ofp placements to place the same set of macros on the given chip. The process is repeated until a final placement is accepted. In one embodiment, to modify the candidate preference, the system may modify one or more vector elements of the candidate preference by respective one or more delta values, with each delta value being in a predetermined value range.

FIG. 20 is a flow diagram illustrating a method 2000 for training an NN to perform macro placement according to one embodiment. Method 2000 may be performed by system 1800 in FIG. 18. Method 2000 begins with the system receiving a set of target trajectories that correspond to placements of respective macros on respective chips in a training set (S2010). The final state in each target trajectory corresponds to the completion of a target placement. The system then searches for a reward function that generates a target reward greater than a learned reward (S2020). The target reward is calculated from the target trajectories and the learned reward is calculated from trajectories generated by the NN. The system further searches for parameters to update the NN such that the NN generates updated trajectories that maximize the learned reward (S2030).

In one embodiment, the process of searching the reward function and searching the parameters is repeated until no reward function can be found that generates the target reward greater than the learned reward. In one embodiment, the reward function is calculated by a second NN to output the target reward and the learned reward. When searching for the reward function, the parameters of the second NN may be updated by applying gradient descent to a loss function defined by a difference between the target reward and the learned reward. In another embodiment, the reward function is a linear combination of a preference and corresponding objectives.

FIG. 21 is a flow diagram illustrating a method 2100 for the placement of unordered macros according to one embodiment. Method 2100 may be performed by system 1800 in FIG. 18. Method 2100 begins with an NN generating a first probability distribution of a macro-order action under a current state of the chip (S2110). The macro-order action is to select a macro from an unordered set of macros to be placed on a chip. The NN further generates a second probability distribution of a positional action under the current state of the chip (S2120). The positional action is to select a coordinate on the chip for placing the macro. The NN samples the macro-order action and the positional action based on the first probability distribution and the second probability distribution, respectively (S2130). Then a macro-order mask is updated to remove the macro which has been placed from the unordered set (S2140), and a positional mask is also updated to block an area on the chip for subsequent placements of remaining macros (S2150).

In one embodiment, the NN is trained to generate the first probability distribution according to a macro-order policy parametrized by a first set of parameters. The NN is further trained to generate the second probability distribution according to an action policy parametrized by a second set of parameters. The first set of parameters and the second set of parameters are trained simultaneously.

When training the NN, the system may receive a set of target trajectories that correspond to placements of respective macros on respective chips in a training set. The final state in each target trajectory corresponds to the completion of a target placement. The system then searches for a reward function that generates a target reward greater than a learned reward, where the target reward is calculated from the target trajectories and the learned reward is calculated from trajectories generated by the NN. The system further searches for parameters to update the NN such that the NN generates updated trajectories that maximize the learned reward.

In one embodiment, the NN may be trained in the following process. The system first uses the NN to sample a set of first trajectories in a sample collection operation according to the stochastic policy. The system then updates the parameters of the NN in a training operation using a loss function calculated from the first trajectories. The system calculates a final reward value from a plurality of reward values in an evaluation operation. Each reward value is calculated based on a final state of one of second trajectories generated by the NN having the updated parameters. The process is repeated until the final reward value reaches a threshold.

Various functional components or blocks have been described herein. As will be appreciated by persons skilled in the art, the functional blocks will preferably be implemented through circuits (either dedicated circuits, or general-purpose circuits, which operate under the control of one or more processors and coded instructions), which will typically comprise transistors that are configured in such a way as to control the operation of the circuitry in accordance with the functions and operations described herein.

While the invention has been described in terms of several embodiments, those skilled in the art will recognize that the invention is not limited to the embodiments described, and can be practiced with modification and alteration within the spirit and scope of the appended claims. The description is thus to be regarded as illustrative instead of limiting.

What is claimed is:

1. A method for macro placement by a neural network (NN), comprising:
receiving an input including a plurality of objectives and a subspace of preferences, wherein each preference is a vector of weights assigned to corresponding objectives, and each objective is a measurement of a placement characteristic;
training the NN to place macros on a training set of chips to optimize a reward calculated from the objectives and the preferences;
generating, by the NN, a probability distribution of an action under a current state of a chip, the action indicating a coordinate on the chip to place a macro; and
generating, by the NN, a sequence of (state, action) pairs to form a trajectory, wherein a final state in the trajectory corresponds to a completed macro placement.

2. The method of claim 1, wherein training the NN includes encoding a sampled preference from the subspace into a latent state of the NN.

3. The method of claim 1, wherein the reward is calculated from a linear combination of a sampled preference from the subspace and the corresponding objectives.

4. The method of claim 1, wherein generating the probability distribution of the action further comprises:
applying a mask to the probability distribution to produce a masked distribution over the chip, wherein the mask blocks off areas on the chip; and
based on a stochastic policy, sampling the action according to the masked distribution.

5. The method of claim 4, wherein training the NN further comprises:
sampling a set of trajectories in a sample collection operation according to the stochastic policy; and
using the set of trajectories to calculate an update to parameters of the NN.

6. The method of claim 1, wherein generating the probability distribution of the action further comprises:
applying a mask to the probability distribution to produce a masked distribution over the chip, wherein the mask blocks off areas on the chip; and
based on a deterministic policy, choosing the action with a highest probability according to the masked distribution.

7. The method of claim 6, wherein training the NN further comprises:
sampling a set of trajectories in an evaluation operation according to the deterministic policy; and
calculating a final reward value from a plurality of reward values, each reward value calculated based on a final state of one of the trajectories.

8. The method of claim 1, further comprising:
receiving, after the training of the NN, a given preference and a given chip on which a plurality of macros are to be placed;
further training the NN with the given preference and a plurality of stochastically sampled trajectories on the given chip; and
sampling a final trajectory using the further-trained NN to generate the completed macro placement.

9. The method of claim 1, wherein the objectives further include a distance to at least one of a positive anchor and a negative anchor, the positive anchor to attract the placement of a first subset of the macros and the negative anchor to repel the placement of a second subset of the macros.

10. The method of claim 1, further comprising:
generating a set of placements by the NN to place a same set of macros on a given chip, wherein each placement is generated based on a different preference;
receiving an indication of a candidate placement among the set of placements, wherein the candidate placement is generated based on a candidate preference;
modifying the candidate preference to generate p preferences;
generating a subsequent set of p placements by the NN to place the same set of macros on the given chip; and
repeating the receiving of the indication, the modifying of the candidate preference, and the generating of the subsequent set of p placements until a final placement is accepted.

11. The method of claim 10, wherein modifying the candidate preference further comprises:
modifying one or more vector elements of the candidate preference by respective one or more delta values, wherein each delta value is in a predetermined value range.

12. A method for training a neural network (NN) to perform macro placement on a chip, comprising:
receiving a set of target trajectories that correspond to placements of respective macros on respective chips in a training set, wherein a final state in each target trajectory corresponds to completion of a target placement;
searching for a reward function that generates a target reward greater than a learned reward, wherein the target reward is calculated from the target trajectories and the learned reward is calculated from trajectories generated by the NN; and
searching for parameters to update the NN such that the NN generates updated trajectories that maximize the learned reward.

13. The method of claim 12, further comprising:
repeating the searching of the reward function and the searching of the parameters until no reward function can be found that generates the target reward greater than the learned reward.

14. The method of claim 12, wherein the reward function is calculated by a second NN to output the target reward and the learned reward.

15. The method of claim 14, wherein searching for the reward function further comprises:
updating parameters of the second NN by applying gradient descent to a loss function defined by a difference between the target reward and the learned reward.

16. The method of claim 12, wherein the reward function is a linear combination of a preference and corresponding objectives.

17. A method for placement of unordered macros on a chip, comprising:
generating, by a neural network (NN), a first probability distribution of a macro-order action under a current state of a chip, wherein the macro-order action is to select a macro from an unordered set of macros to be placed on a chip;
generating, by the NN, a second probability distribution of a positional action under the current state of the chip, wherein the positional action is to select a coordinate on the chip for placing the macro;
sampling, by the NN, the macro-order action and the positional action based on the first probability distribution and the second probability distribution, respectively;
updating a macro-order mask to remove the macro which has been placed from the unordered set; and
updating a positional mask to block an area on the chip for subsequent placements of remaining macros.

18. The method of claim 17, further comprising:
training the NN to generate the first probability distribution according to a macro-order policy parametrized by a first set of parameters and to generate the second probability distribution according to an action policy parametrized by a second set of parameters, wherein the first set of parameters and the second set of parameters are trained simultaneously.

19. The method of claim 17, further comprising:
training the NN to generate the first probability distribution and the second probability distribution, wherein training the NN further comprises:
receiving a set of target trajectories that correspond to placements of respective macros on respective chips in a training set, wherein a final state in each target trajectory corresponds to completion of a target placement;
searching for a reward function that generates a target reward greater than a learned reward, wherein the target reward is calculated from the target trajectories and the learned reward is calculated from trajectories generated by the NN; and
searching for parameters to update the NN such that the NN generates updated trajectories that maximize the learned reward.

20. The method of claim 19, wherein training the NN further comprises:
sampling, by the NN, a set of first trajectories in a sample collection operation according to the stochastic policy;
updating parameters of the NN in a training operation using a loss function calculated from the first trajectories;
calculating a final reward value from a plurality of reward values in an evaluation operation, each reward value calculated based on a final state of one of second trajectories generated by the NN having the updated parameters; and
repeating the sample collection operation, the training operation, and the evaluation operation until the final reward value reaches a threshold.
